(19) United States
(12) Patent Application Publication
(10) Pub. No.: US 2025/0348632 A1
(43) Pub. Date: Nov. 13, 2025

(54) Construction Specification Generation

(71) Applicant: David Stutzman, Tuckahoe, NJ (US)

(72) Inventor: David Stutzman, Tuckahoe, NJ (US)

(73) Assignee: Conspectus Inc., Tuckahoe, NJ (US)

(21) Appl. No.: 18/657,342

(22) Filed: May 7, 2024

(51) Int. Cl. G06F 30/20

(52) U.S. Cl. CPC G06F 30/20

(57) ABSTRACT

Systems and methods for generating a construction design such as a construction specification, permissioned at a project level and instantiating a construction design template for receiving user input, verifying user entries via compliance data and completing the construction design based on the template, user entry, and compliance data.

### TECHNICAL FIELD

The present disclosure is related generally to the construction industry and, more particularly, to systems and methods for facilitating specification generation for construction projects. Moreover, in various embodiments, multiple systems are combined to accomplish much more than construction specifications.

### BACKGROUND

In order for a construction project to be executed successfully, the project design should be fully and clearly communicated from the owner to the designer to the contractor and workers. An important part of that chain of communication is what is known as the “construction specification.” A construction specification may be part of the contract documents that accompany and control the construction of buildings and infrastructure projects.

Whether for residential, commercial, civil, or industrial builds, construction specifications describe the quality and performance of building materials, consistent with local codes and standards, as opposed to dictating material quantities and locations. While known standards such as MasterFormat® may provide names and numbers usable to reference materials, they do not provide an easy way to actually create construction specifications.

A construction specification may be categorized or subdivided by work types and intended results. These categories may be further subdivided into sections addressing, for example, material types or work products as they relate to the relevant category. For example, tile roofing and tile flooring may be specified in the construction specification in subdivisions of different categories. The ordering of specification divisions or categories may be based on their time of usage during the project.

The construction specification takes on additional importance if there is a discrepancy between the construction specification and the project drawings. Indeed, the construction specification can overrule the drawings in the event of discrepancies if the parties to the project contract so agree. Some public agencies actually require that the specifications overrule the drawings.

Construction specifications can be written to require certain performance results, or may be written to additionally describe how such performance is to be achieved, e.g., standards, techniques and so on. In addition, a construction specification may actually require the use of specific proprietary products, services or service providers. Further, a construction specification may be “closed” (i.e., listing necessary products), or “open” (i.e., allowing substitutions by the contractor). Finally, a construction specification may be a combination of the aforementioned formats.

Responsibility for the construction specification preparation typically falls to the architect, but the actual drafting is often outsourced to specialized construction specification writers. While these writers have generally become quite proficient at their task, there is still unavoidable waste and inefficiency in the task as it is currently executed, and there is a need for a tool that provides accurate and efficient specification preparation.

Before proceeding to the remainder of this disclosure, it should be appreciated that the disclosure may address at least a portion of the shortcomings listed or implicit in this Background section. However, any such benefit is neither a limitation on the scope of the disclosed principles nor of the attached claims, except to the extent expressly noted in the claims.

Additionally, the discussion of technology in this Background section is reflective of the inventors' own observations, considerations, and thoughts, and is not intended to be, to accurately catalog, or to comprehensively summarize any prior art reference or practice. As such, the inventors expressly disclaim this section as admitted or assumed prior art. Moreover, the identification or implication herein of one or more desirable courses of action reflects the inventors' own observations and ideas, and should not be assumed to indicate an art-recognized desirability.

### BRIEF DESCRIPTION OF THE SEVERAL VIEWS OF THE DRAWINGS

While the appended claims set forth the features of the present techniques with particularity, these techniques, together with their objectives and advantages, may be best understood from the following detailed description taken in conjunction with the accompanying drawings of which:

FIG. 1 is a schematic representation of a computerized device within which various embodiments of the disclosed principles may be implemented;

FIG. 2 is a schematic drawing showing an operational environment of the construction specification tool in accordance with an embodiment of the disclosed principles;

FIG. 3 illustrates a process for construction specification generation in accordance with an embodiment of the disclosed principles;

FIG. 4 is an example screen shot showing a log in screen in accordance with

an embodiment of the disclosed principles;

FIG. 5 is an example screen shot showing a first screen after logging in wherein users see their projects and the basic status of each project in accordance with an embodiment of the disclosed principles;

FIG. 6 is an example screen shot showing the first screen when creating a new project in accordance with an embodiment of the disclosed principles;

FIG. 7 is an example screen shot showing a project dashboard with the status and authors for each document included in the project in accordance with an embodiment of the disclosed principles;

FIG. 8 is an example screen shot showing a checklist to begin developing a project after creating a new project in accordance with an embodiment of the disclosed principles;

FIG. 9 is an example screen shot showing another checklist similar to the checklist of FIG. 8 in accordance with an embodiment of the disclosed principles but wherein the checklist is used with documents of a first format to make a link from one format to the other;

FIG. 10 is an example screen shot showing the location to collect many of the owner's project requirements and regulatory requirements affecting the project in accordance with an embodiment of the disclosed principles;

FIG. 11 is an example screen shot showing an Element B having a fairly complete description as well as the link connection to documents of another format for each of the component keyword phrases in accordance with an embodiment of the disclosed principles;

FIG. 12 is an example screen shot showing a Specification Section that illustrates the result of connecting one format to the other in accordance with an embodiment of the disclosed principles;

FIG. 13 is an example screen shot showing a default template for use in the event no master specification exists for a particular document in accordance with an embodiment of the disclosed principles;

FIG. 14 is an example screen shot showing Properties, providing a way to show the status of each project document in accordance with an embodiment of the disclosed principles; and

FIG. 15 is a process flow diagram including external interactions in accordance with an embodiment of the disclosed principles.

### DETAILED DESCRIPTION

Before discussing embodiments of the disclosed principles in full detail, an overview of certain embodiments is given to aid the reader in understanding the later more detailed discussion.

As noted above, construction specifications may be prepared by the project architect or, more frequently, by specialized construction specification writers. However proficient these writers may become, there is unavoidable waste and inefficiency inherent in the task as it is currently executed.

However, in an embodiment of the disclosed principles, a construction specification preparation tool is provided that yields accurate and efficient specification preparation. In an embodiment of the disclosed principles, the specification generation tool is executed on a computerized device to enable the accurate and efficient creation of a project construction specification.

Moreover, in various embodiments, multiple systems are combined to accomplish much more than construction specifications, being capable of capturing owner project requirements, performance requirements, design criteria, design decisions, system descriptions, construction specifications, and commissioning and operations requirements in addition to the material included in traditional construction specifications. The system in essence provides design management, akin to construction management.

The tool combines suitable construction specification conventions such as MasterFormat® (sometimes herein referred to as MF), UniFormat® (sometimes herein referred to as UF), and UNIFORMAT II or other construction specification conventions that provide numbers and titles, and cross-checks entered data to eliminate inconsistencies and discrepancies that might otherwise occur. The tool operates in one aspect by prepopulating known quantities, accessing and incorporating applicable rules and codes, and presenting available options for user selection.

With this overview in mind, and turning now to a more detailed discussion in conjunction with the attached figures, the techniques of the present disclosure are illustrated as being implemented in or via a suitable device environment. The following device description is based on embodiments and examples within which or via which the disclosed principles may be implemented, and should not be taken as limiting the claims with regard to alternative embodiments that are not explicitly described herein.

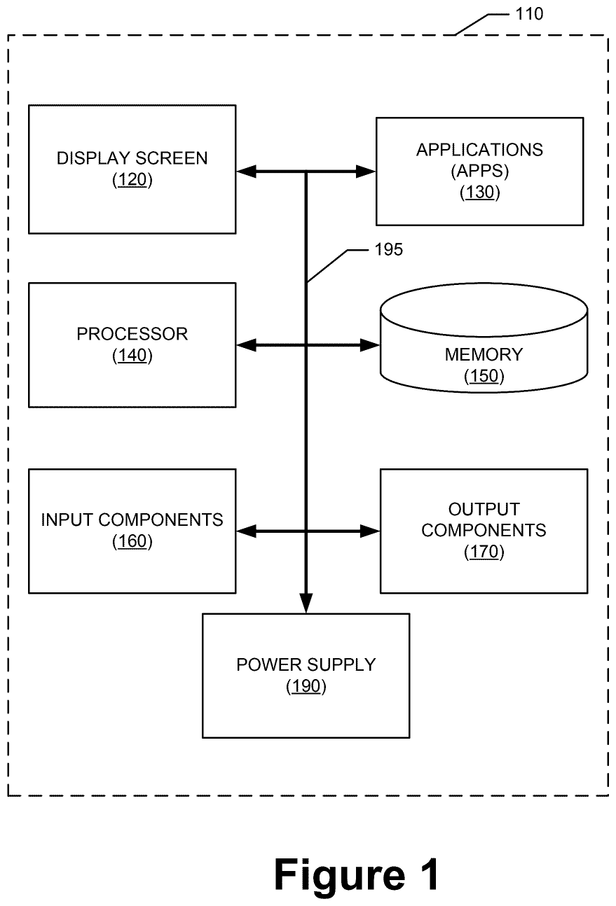

Thus, for example, while FIG. 1 illustrates an example computer environment with respect to which embodiments of the disclosed principles may be implemented, it will be appreciated that other device types may be used, including but not limited to servers, laptop computers, desktop computers, smartphones, workstation devices and other suitable devices. It will be appreciated that additional or alternative components may be used in a given implementation of the disclosed principles depending upon user preference, component availability, price point and other considerations.

In the illustrated embodiment, the components of the user device 110 include a display screen 120, applications (e.g., programs) 130, a processor 140, a memory 150, one or more input components 160 such as RF input facilities or wired input facilities, including, for example, one or more antennas and associated circuitry and logic. The antennas and associated circuitry may support any number of protocols, e.g., WiFi, Bluetooth, cellular, etc.

The device 110 as illustrated also includes one or more output components 170 such as RF (radio frequency) or wired output facilities. The RF output facilities may similarly support any number of protocols, e.g., WiFi, Bluetooth, cellular, etc., and may be the same as or overlapping with the associated input facilities. It will be appreciated that a single physical input may serve for both transmission and receipt.

The processor 140 can be a microprocessor, microcomputer, application-specific integrated circuit, or other suitable integrated circuit. For example, the processor 140 can be implemented via one or more microprocessors or controllers from any desired family or manufacturer. Similarly, the memory 150 is a nontransitory media that may (but need not) reside on the same integrated circuit as the processor 140. Additionally or alternatively, the memory 150 may be accessed via a network, e.g., via cloud-based storage. The memory 150 may include a random access memory (i.e., Synchronous Dynamic Random Access Memory (SDRAM), Dynamic Random Access Memory (DRAM), RAMBUS Dynamic Random Access Memory (RDRM) or any other type of random access memory device or system). Additionally or alternatively, the memory 150 may include a read-only memory (i.e., a hard drive, flash memory or any other desired type of memory device).

The information that is stored by the memory 150 can include program code (e.g., applications 130) associated with one or more operating systems or applications as well as informational data, e.g., program parameters, process data, etc. The operating system and applications are typically implemented via executable instructions stored in a non-transitory computer readable medium (e.g., memory 150) to control basic functions of the electronic device 110. Such functions may include, for example, interaction among various internal components and storage and retrieval of applications and data to and from the memory 150.

Further with respect to the applications and modules, these typically utilize the operating system to provide more specific functionality, such as file system service and handling of protected and unprotected data stored in the memory 150. In an embodiment, modules are software agents that include or interact with hardware components such as one or more sensors, and that manage the device 110's operations and interactions with respect to the described embodiments.

With respect to informational data, e.g., program parameters and process data, this non-executable information can be referenced, manipulated, or written by the operating system or an application. Such informational data can include, for example, data that are preprogrammed into the device during manufacture, data that are created by the device or added by the user, or any of a variety of types of information that are uploaded to, downloaded from, or otherwise accessed at servers or other devices with which the device is in communication during its ongoing operation.

In an embodiment, a power supply 190, such as a battery or fuel cell, is included for providing power to the device 110 and its components. Additionally or alternatively, the device 110 may be externally powered, e.g., by a wall socket, vehicle battery or other power source. In the illustrated example, all or some of the internal components communicate with one another by way of one or more shared or dedicated internal communication links 195, such as an internal bus.

In an embodiment, the device 110 is programmed such that the processor 140 and memory 150 interact with the other components of the device 110 to perform a variety of functions. The processor 140 may include or implement various modules and execute programs for initiating different activities such as launching an application, transferring data and toggling through various graphical user interface objects (e.g., toggling through various display icons that are linked to executable applications). As noted above, the device 110 may include one or more display screens 120. These may include one or both of an integrated display and an external display.

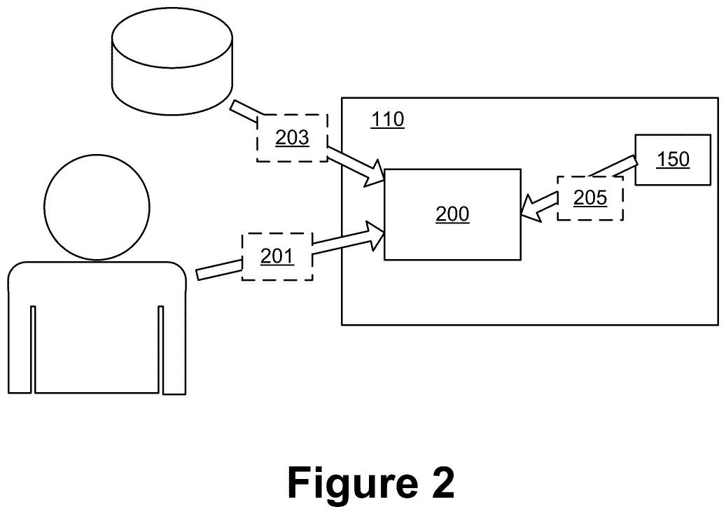

FIG. 2 is a schematic diagram showing the data flow within an embodiment of the described principles. As can be seen, the described tool 200, which may be a software module running on the user device 110, receives as input certain user-specified construction specification information 201, externally-sourced compliance information 203 (i.e., local or nonlocal codes and or rules that affect the construction specification), and internally-sourced construction specification format information 205.

The user-specified construction specification information 201 may comprise project-specific values such as certain construction materials, performance results, operational requirements, construction methods, construction standards, specific proprietary products, services or service providers. This information may be received by the user device 110, and hence the construction specification tool 200, via one or more user-input facilities (160) of the device 110, e.g., a device keyboard.

The externally-sourced compliance information 203 may comprise codes, rules or ordinances that control requirements of the project (e.g., number of exits), the usage of one or more materials (e.g., fire brick) or techniques (e.g., concrete laying or curing techniques). Again, this information may be received by the user device 110, and hence the construction specification tool 200, via one or more user-input facilities (160) of the device 110, and more particularly, a hard-wired or wireless connection to a source of such information.

Finally, the construction specification format information 205 may be internally-stored and/or internally-generated formatting information that specifies a format of the construction specification, e.g., by specifying categories or classes, subcategories or subclasses, and so on. As noted above, there are several available formats with which one may wish to comply, and the user may wish to use some, all, or none of such publicly available formats, or may mix portions of different formats to achieve an ideal balance.

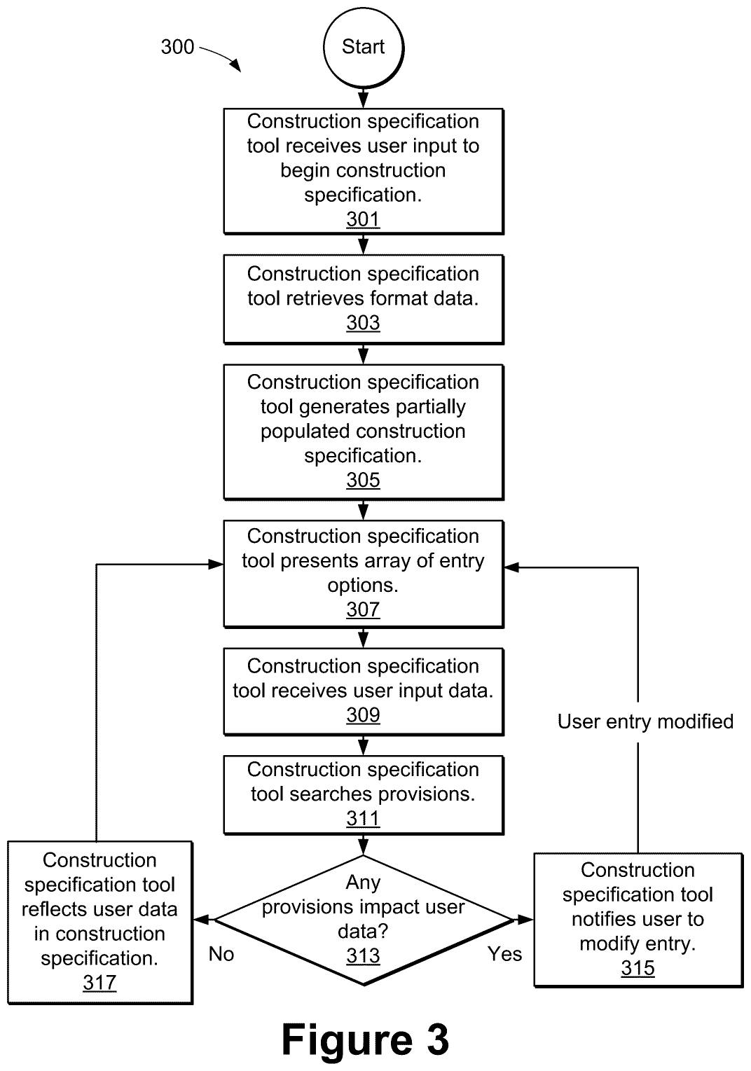

Turning to FIG. 3, this figure shows an exemplary process 300 for the generation of a construction specification in accordance with an embodiment of the described principles. It will be appreciated that the process 300 may be implemented via computer-executable instructions, e.g., program code, stored on, and read from, a computer-readable medium, e.g., a hard drive memory, optical drive memory or solid state memory of the user device 110. Thus, these steps reflect not only an exemplary process but also the computer-readable instructions necessary to implement the exemplary process.

At stage 301 of the process 300, a construction specification tool (e.g., FIG. 2 element 200) receives user input to begin a construction specification. The construction specification tool then retrieves format data at stage 303, and generates a partially populated construction specification in keeping with the retrieved format data at stage 305.

The construction specification tool then presents an array of entry options to the user of the device at stage 307. The entry options may include, for example, options to specify a task, material, technique and so on. At stage 309 of the process 300, the construction specification tool receives user input data related to at least one of the displayed entry options, e.g., a user selection or specification of a task, material or technique.

The construction specification tool then searches rules, laws and ordinances at stage 311 to identify provisions that may be applicable to the received user input data. The searched data may be external, i.e., an external memory or server, or internal, i.e., the device's own memory (e.g., memory 150, FIG. 1). At stage 313, the construction specification tool determines whether any identified provision impacts the entered user data. If it is determined at stage 313 that an identified provision does impact the entered user data, then the process 300 flows to stage 315, wherein the construction specification tool notifies the user to modify the entry. Otherwise, the process 300 continues to stage 317 from stage 313, wherein the user data is reflected in the construction specification. At this point, the process 300 may return to stage 307 to continue guiding the user through the creation of the construction specification.

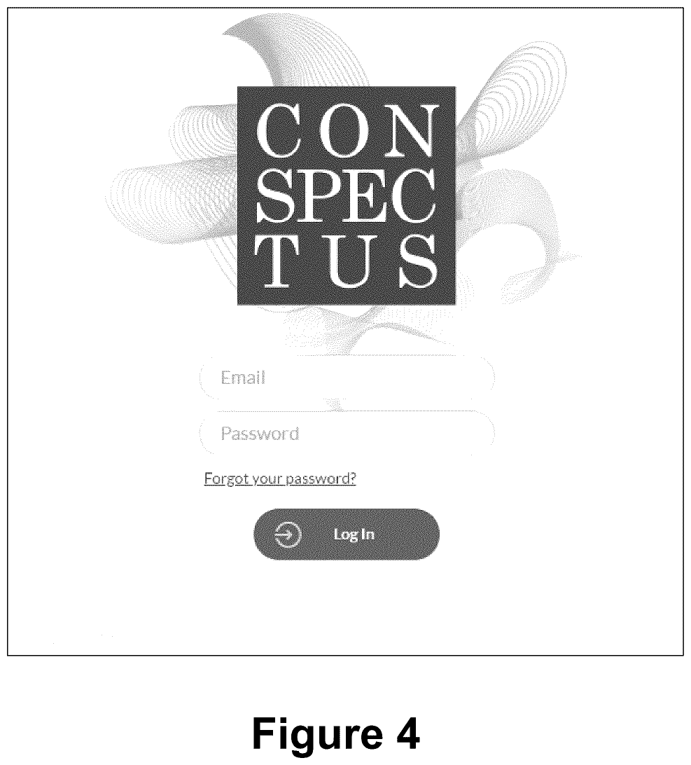

Having discussed the hardware and operations of the construction specification tool, FIGS. 4-15 provide examples of the creation and manipulation of a sample document using the tool.

FIG. 4 is the log in screen where the system is accessed after creating an account by being invited to participate in the first project. Once an account is created, users can access all projects for which they have permissions after logging in. Permissions may be set in any suitable manner, but in an embodiment, permissions for specific users are set by the project creator or a project administrator for a given project.

When a user attempts to access a particular project, a check may be run first to ensure that the user is permitted access for that project. Access is then granted, if permitted, or alternatively the user is shown a denial screen. Failed access attempts may also be logged and reported to the administrator or other personnel to allow expeditious maintenance of permission lists as well as to detect any potential nefarious activity.

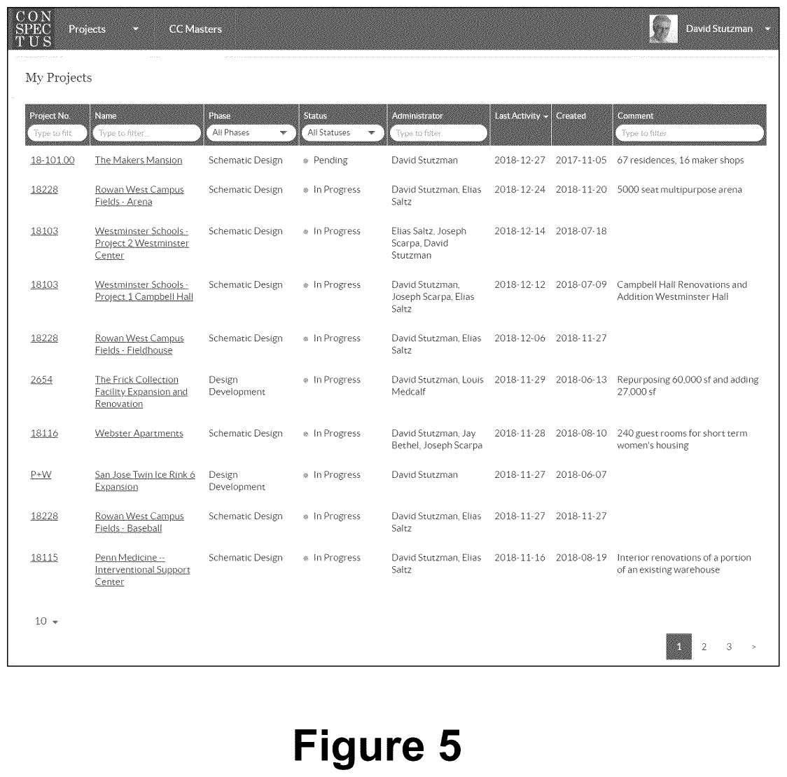

FIG. 5 is the first screen after logging in, where users see their projects (projects to which they have been granted access) and the basic status of each project, including, for example, the last activity.

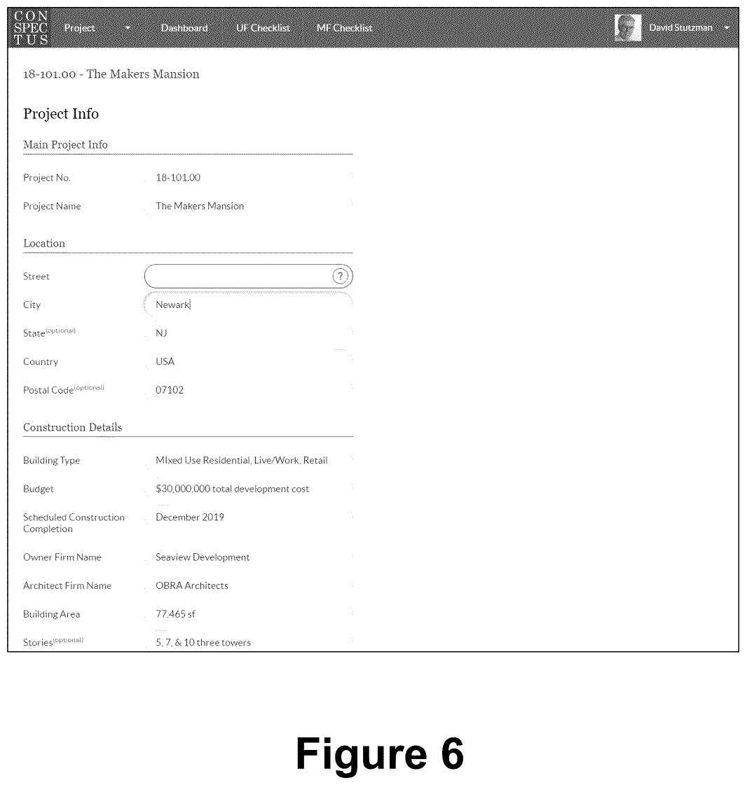

FIG. 6 is the first screen when creating a new project. You can see the street field is red, meaning the field should be completed before the project can be created. The system monitors each non-optional field in this window to ensure all are completed to begin a new project.

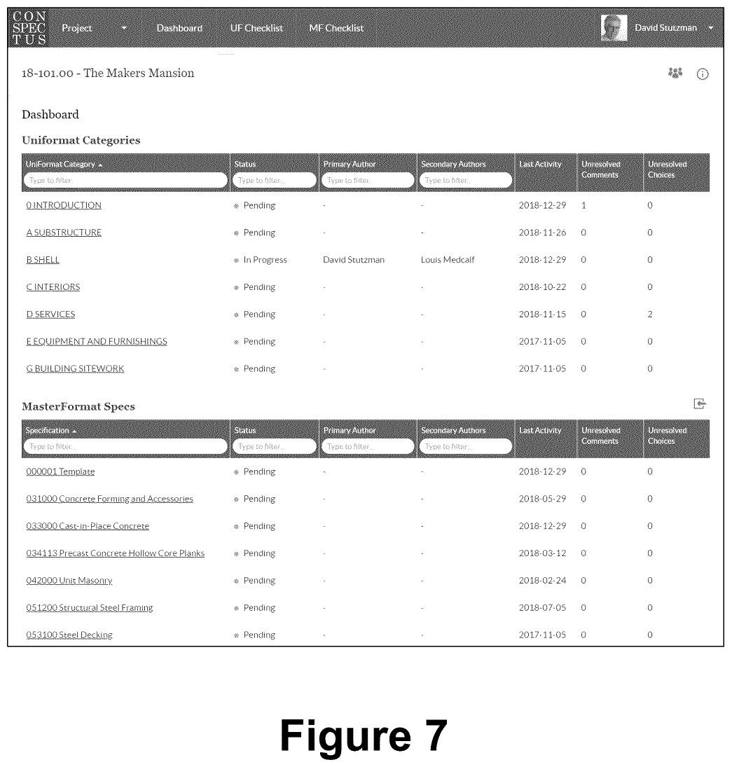

FIG. 7 shows project dashboard showing the status and authors for each document included in the project. Most importantly it provides a snapshot view of the number of unresolved comments and specifications choices in each document. This lets users sort and filter to find documents that are incomplete and those with the most unresolved issues.

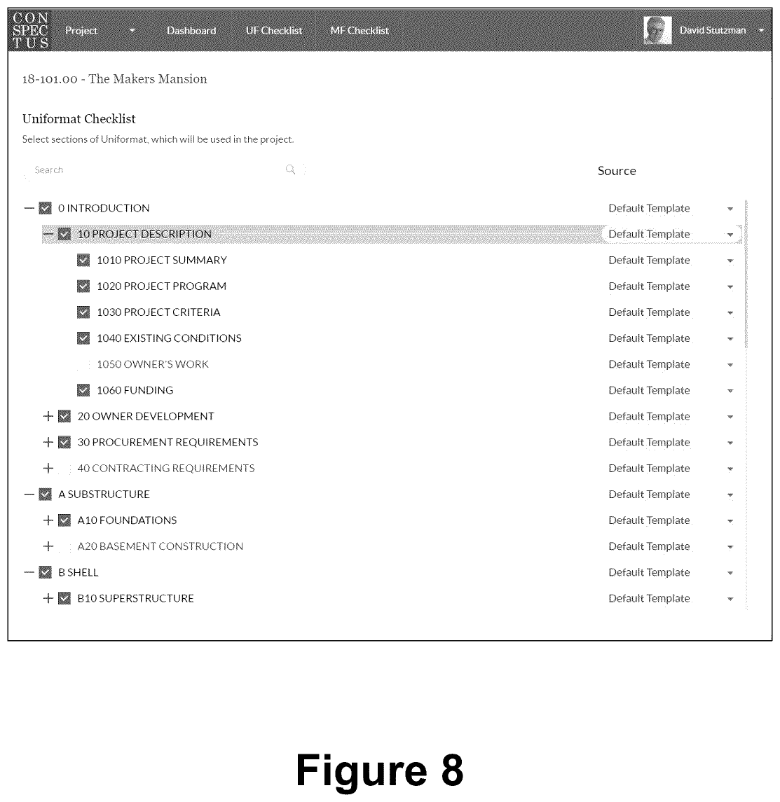

FIG. 8 shows a checklist to begin developing a project after creating a new project. Here each of the major elements is selected to be added to the project. Additionally the appropriate default, master, or project template to apply to the project can be selected for each document.

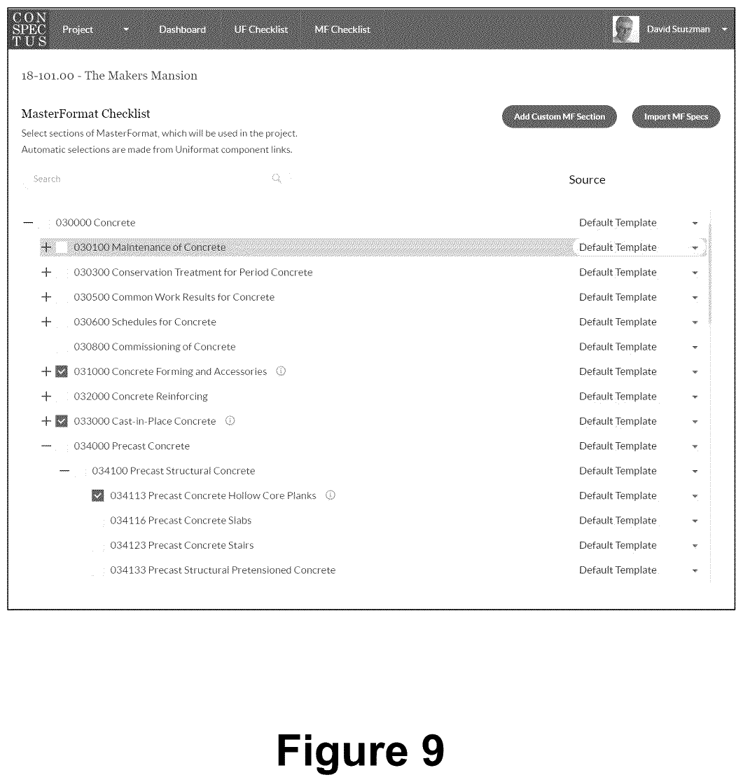

FIG. 9 shows another checklist similar to the checklist of FIG. 8 but wherein the checklist is used with documents of a first format to make a link from one format to the other.

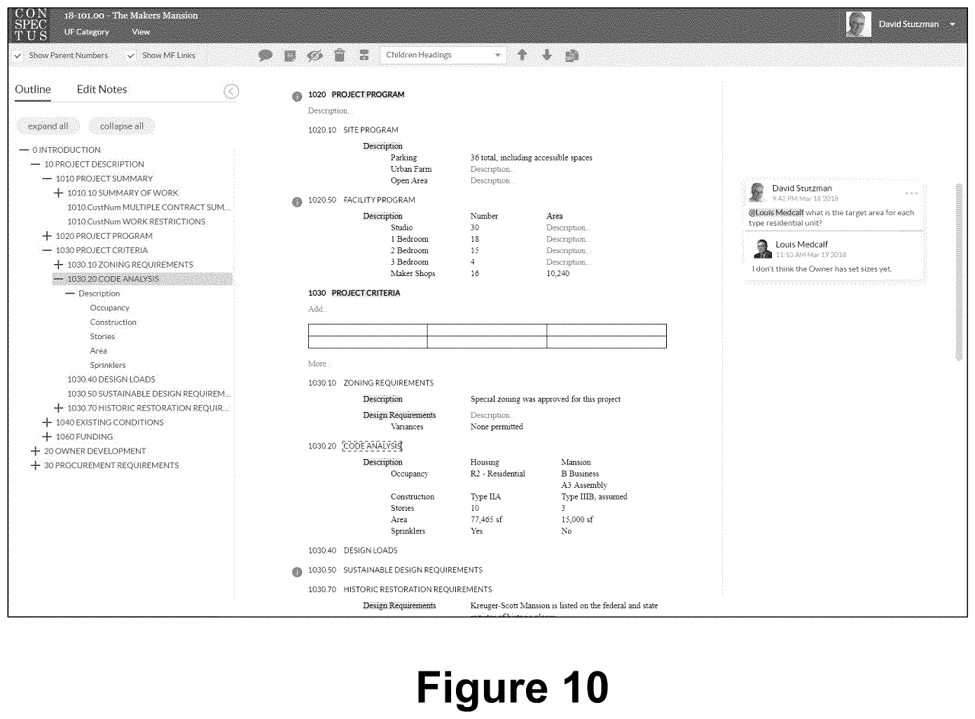

FIG. 10 shows the location to collect most of the owner's project requirements and regulatory requirements affecting the project. In an embodiment, code data entries are used to help make high level specification edits. You can also see the threaded commenting feature where questions can be asked, answered and resolved. These comments are tracked on the project dashboard until they are marked as resolved.

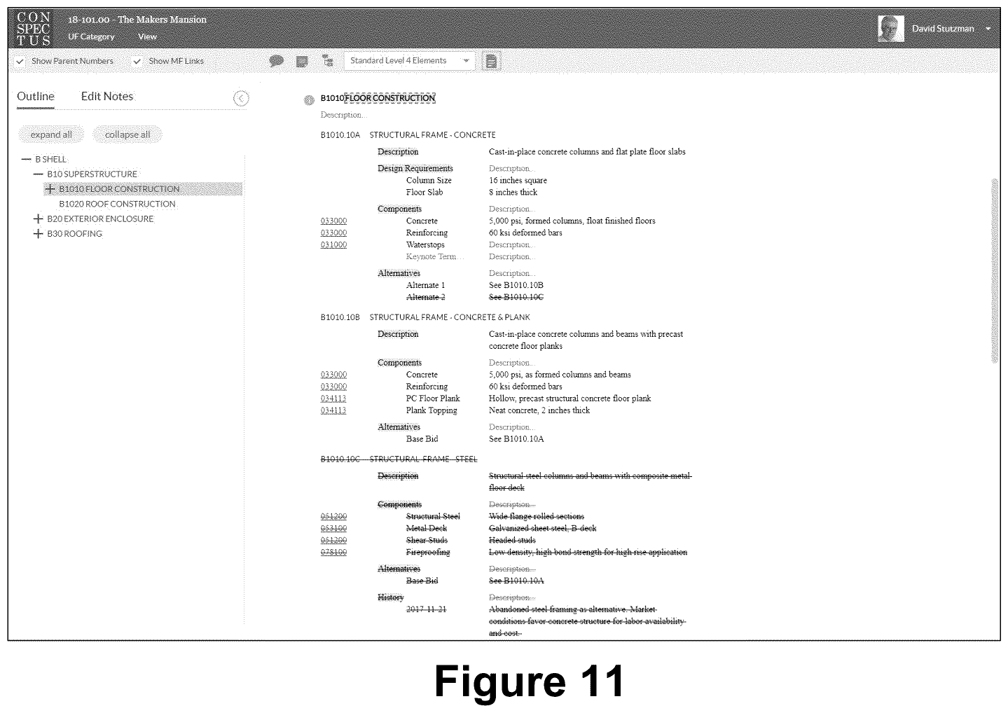

FIG. 11 shows an Element B having a fairly complete description as well as the link connection to documents of another format for each of the component keyword phrases.

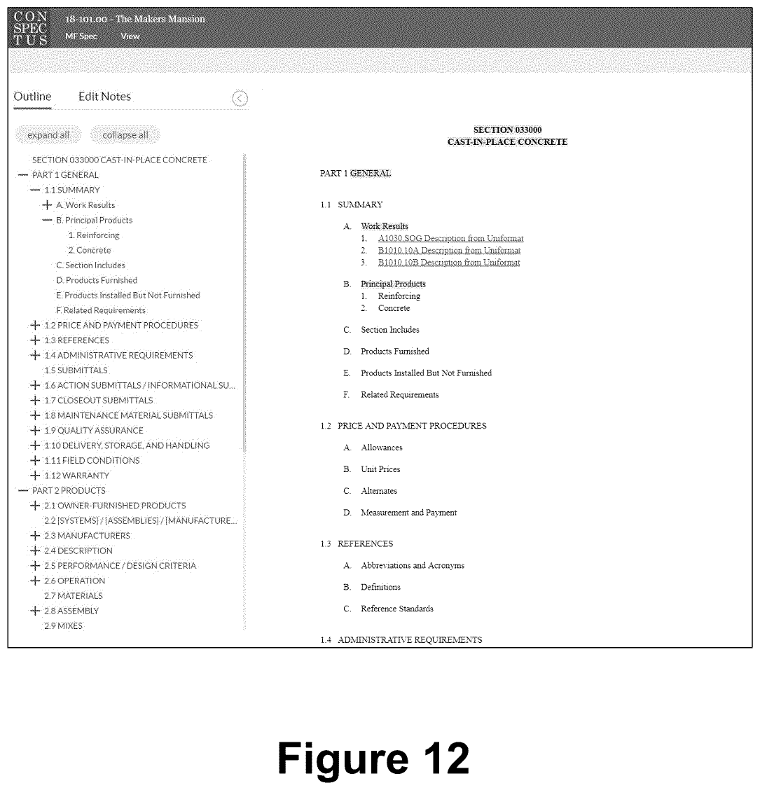

FIG. 12 shows a Spec Section that illustrates the result of connecting one format to the other. The work results and principal products are automatically populated with text directly from UniFormat (i.e., parts of either or both UniFormat and UNIFORMAT II). Because this is a draft view, the links are shown instead of the actual text that will be displayed in the final view.

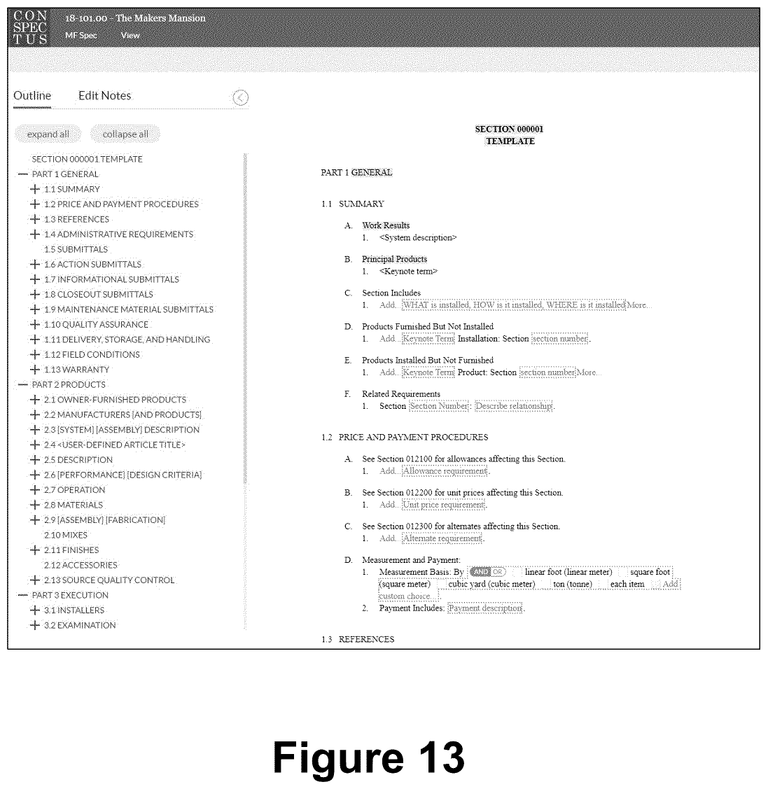

FIG. 13 shows a template that will serve as the default template if no master specification exists for a particular document. The template shows instructional text objects as fill-in-the-blanks and a choice group where the specifier can make choices with checkboxes to complete the specification. When all the choices are resolved, the dashed pink outlines are shown in solid blue and the project dashboard will show zero unresolved choices.

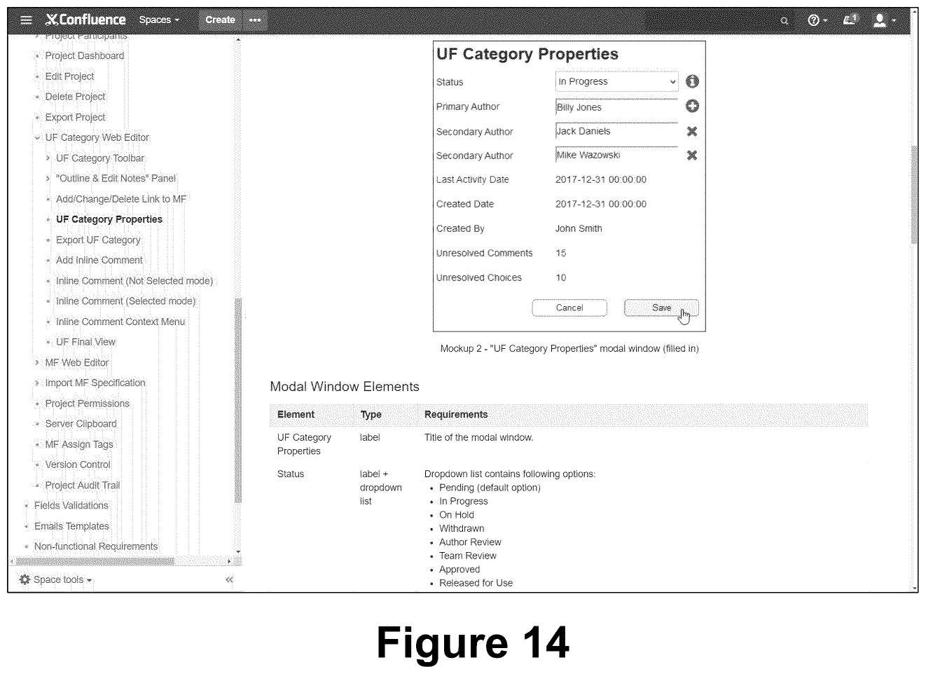

FIG. 14 shows Properties and provides a way to show the status of each project document. The available status options are shown below the sample window. The system will check the unresolved items before allowing the document to be marked “Released for Use.” Documents of either format work the same way in this regard.

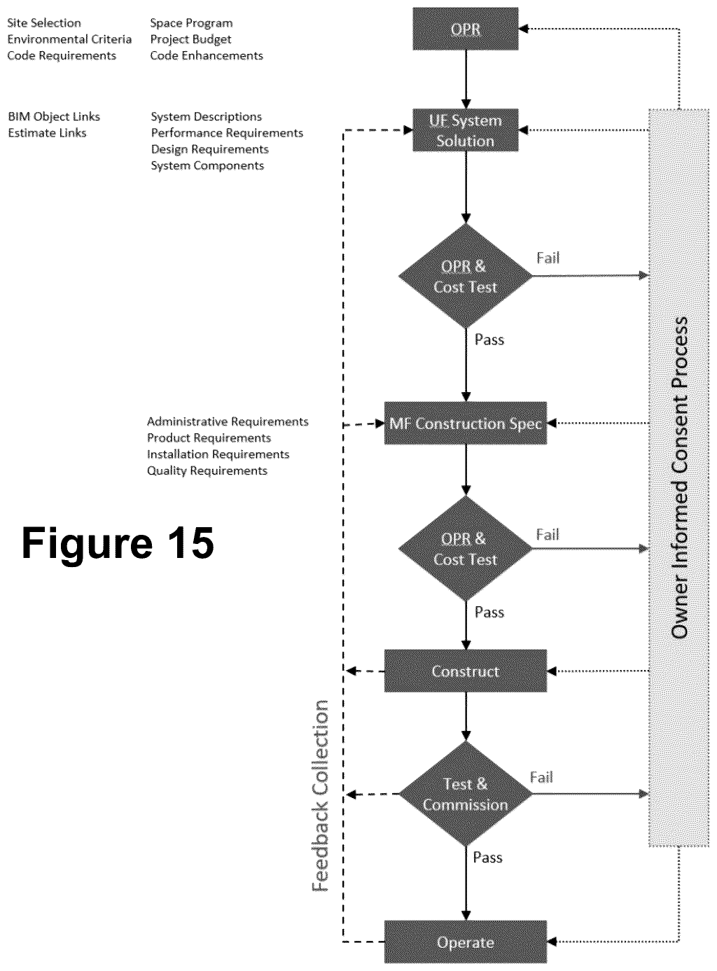

Turning to FIG. 15, this figure shows a process flow including external interactions in accordance with an embodiment of the disclosed principles. UniFormat (UF) element descriptions are concise statements about each required system and assembly. Information is included to identify the makeup, define the required quality, and to permit an estimator to determine the cost of each entire assembly. The UF specifications are written for the entire project team, but without the technical detail of MasterFormat (MF) specifications that is unnecessary to understand the design response to the Owner Project Requirements (sometimes referred to herein as OPR).

The described system, in an embodiment, leverages the UF Introduction (see below) to document the OPR. Much of the OPR, such as environmental and minimum zoning and code criteria, can be generated as soon as the approximate site is known. The owner may enhance the minimum regulatory requirements since these requirements only establish the minimum acceptable building that can be legally constructed. Whatever enhancements are desired beyond the minimum, they should be documented to ensure the design team understands the owner is establishing a greater standard than the codes require.

The required building elements are selected for the project from the UF checklist shown in FIG. 8. The described system, in an embodiment, uses standard UF organization for the Level 1-Level 3 titles. It allows for both standard and custom Level 4 numbers and titles. The rationale is that Level 4 numbers and title should match BIM assembly numbers and titles. If a particular project includes three exterior wall assemblies numbered EW-1, EW-2, and EW-3, then UF will adapt to use the same numbering scheme. The subheadings below Level 4 (see, e.g., FIGS. 10 and 11) are standardized to ensure consistent element descriptions throughout the UF documentation. The basic content of each subheading is described below and is followed by a more specific example showing how the concepts are implemented.

The UF system description is linked to the MF construction specification via the system components. When the components are known, the keyword term is linked via the MF Number to the MF specification section where the component will be specified. Completing the link using the MF checklist shown in FIG. 9 automatically adds the MF specification as a project document. The keyword term is also automatically added to the MF specification as a principle product (shown in FIG. 12) that should be included in the MF specification.

Integrated Building Information: the described system, in an embodiment, produces Integrated Building Information. The tool permits integration of OPR and UF and MF specifications, in a single location in a single platform. The information is available in total or in part, specific to users' project roles.

Architects can view the OPR to ensure the design problem is understood as UF is created in response. The owner can view the UF system descriptions to verify the designers responded correctly to the OPR. Estimators can quickly assess the UF systems and components that should be priced to help guide design decisions. Construction manager can view the MF specifications to understand the products needed to schedule the work and build the UF systems. All participants (with appropriate permissions) can see all the data at any point in time to understand the relationship of the individual parts to the entire project.

An example flow in the described system, in an embodiment, is as follows: Start Day One: The owner decides a building is required. Begin documenting the project requirements. Capture decisions as they occur so the project progress is always forward toward completion. Record overall regulatory, environmental, and performance requirements that should be considered for every design decision.

Establish the Project: Follow the prescribed workflow to record basic project data, Invite project participants, set permissions, and begin identifying project documents. Set the default source documents, selecting masters or another project. Build the project documents using checklists. Determine the source, independently, for each individual document when added to the checklist.

Collaborative Development: Cloud based software accessed via internet browser allows an unlimited number of participants at the same time. Participation is controlled by permissions set at a firm and project level. One may invite the entire project team as participants, including the owner, designer, specialty consultant, contractor, subcontractor, material supplier, and others, without limit and as appropriate. Establish permissions as viewers, commenters, editors, and authors to suit their role and expertise.

Commenting: Direct specific comments via mention to specific participants in the best position to respond or provide necessary approvals. Mentioned users will receive an email with the comment and a link to see the comment in context. The notices are user-selectable either instant or a periodic summary digest. Respond directly to the comment to build the discussion thread associated with the document text. Mark the comment resolved when the discussion concludes and approval is provided. In an embodiment, users are enabled to make general comments relating to an entire document without attaching the comment to specific text. Users may also generate a list of unresolved comments with links to navigate directly to each one.

Active Users (future): Know who is actively reviewing and editing project documents by seeing avatars of each active participant. Jump to the location of any participant to actively collaborate. Chat, via instant message, with one or all active participants to review and resolve document questions, instantly.

Dashboard Status: Monitor document development in the project dashboard. See what documents are included, who is responsible, the last update, and how many unresolved comments and editing choices remain to be completed. Sort and filter the dashboard list to find the documents that are incomplete and those that need approval from responsible parties.

Document Status and Record Control: Set and change the status of each document throughout the progress of the project from “pending” to “released for use.” Save versions of individual documents for convenience. Create specific issues of all documents and releases of select documents saved to immutable storage for the record at development milestones. Compare two document records to see what changes occurred during the document development. Restore text to a previous state from the saved records. Compare two project issues and releases to see what documents changed during the project development.

Document Approval Workflow: Documents can be used, officially, only when approved. The process is controlled by an automatic workflow to ensure all defined quality steps and sign-offs are completed. Authority to give final approval is reserved to specific project participants by project permissions.

Contract Document Set (future): Display the latest complete set of current project documents compiled from all issues and all releases. Only the latest released for use version of each document will be shown so there is no chance of working with old data.

Audit Trail: Monitor the activity history on each page to understand who is participating in the project development and what and when events and actions occurred. The system permits queries and report generation to aid discovery for design and construction claim resolution.

Controlled Structure: Enter text knowing the structure and formatting will always be correct following explicit rules. Editing features are contextual. Only software-controlled functions are permitted.

Global and Document Tagging: User tagging will control what document text is available for use with a specific project. Set global tags by geography, client, deliverable, code data, delivery method, and sustainability. Assign document tags by work results, principal products, and applications. Create your own tags for your specific purposes. The list is endless.

Document Variables (future): Develop lists of standardized text, defined terms, referenced standards, and other terminology that should be set once and applied uniformly throughout. Simply insert a document variable at any location. The variable is an object representing the information contained in the referenced list. Update the list and the terminology is automatically updated everywhere the variable is inserted.

Global Search: Find words and phrases used in all documents in a single project or all projects. Include master documents in the search too. Hone the search results by selecting what parts of documents the system shall search. See the location list with links to the search results location.

Organize Data in Tables: Sometimes tables are the most effective way to communicate lots of data. Insert tables of any size. Manipulate the table after insertion. Reposition the table, resize columns and rows, merge cells, and apply formatting to communicate information clearly.

Include Images: A picture is worth a thousand words. Insert assembly or product images to complement the text. Select an external image file for insertion. Control the image by resizing, positioning, and setting word-wrap parameters.

Hyperlinking (future): Create a hyperlink to a location within a project document, to a website, or to an external file. Connect project resources as part of the project record and to help inform document users about selected systems and products and design decisions required to complete a project or create a master document.

Reporting: Generate multiple reports to aid specifications development and construction administration. Report user selected specification article titles to understand the extent of each requirement, such as mockups, and to adjust the specifications to suit the project requirements. List required construction submittals and closeout documents to serve as project checklists.

Master Document Authoring: Create master UF and MF documents directly in the system, by importing legacy documents, or by allowing project documents to flow up to a master status. Develop and maintain multiple masters, if needed, as the starting point for future projects. Begin with a blank template or a master template maintained within the system.

Master Library Maintenance: Update the masters globally or selectively. The system automatically notifies project administrators when master revisions affect project documents. Compare the source master document with the revised master document and the current project document to see if the change is applicable to the project. Apply all or selected master revisions to project documents.

Edit Notes: Capture corporate knowledge in edit notes. Explain what should be specified and how choices should be made. Give guidance learned from experience to help ensure future projects benefit from lessons learned. Create the edit notes in concert with the document content as a teaching tool for staff development.

Import Existing MF DOCX Specifications: A great deal of corporate knowledge exists in existing MF master specifications. This legacy knowledge will be retained with a simple import to preserve existing documents, including embedded editing notes, tables, and images.

Export UF and MF to DOCX and PDF Specifications: Apply document headers and footers using custom text and system project and document data. Edit formatting styles to match project requirements. Automatically generate the project table of contents for the exported documents. Export though possible, is not necessary. People needing access can be invited as viewers only. Maintaining the data within the described system, in an embodiment, ensures the integrity of the data for the entire team and ensures the full advantage of an integrated data set is delivered to the owner.

Feedback and Inform: Continue collecting feedback data from constructing, commissioning, and operating and maintaining the building. Each phase presents challenges and opportunities to improve the record data for ongoing maintenance and future modifications.

Establish Firms: When companies need to control their own destiny, privately, establish a firm within the described system, in an embodiment, Create and maintain the firm master documents, firm projects, and firm participants all under complete control of the individual firm. The described system, in an embodiment, can accommodate firm custom feature sets, on request.

Establish Prototype Project Templates: Different project types may require different project master documents. Create a prototype project as a template to start similar project types. Rely on overall master document updates to keep the prototypes and the resulting project documents current. Revisions made to master documents automatically flow down to all other documents derived from the master.

Integration with External Software: The described system, in an embodiment, is built with an open application programming interface (API) to enable connection to other industry software systems. The construction industry relies on building information modeling (BIM) software such as Revit and estimating software such as R.S. Means. The building geometry controlled by BIM should be coordinated with the systems descriptions controlled by the specifications to allow accurate estimating to confirm project costs against budgets. The described system, in an embodiment, connects BIM objects with specification systems descriptions to inform estimates. Conversely the described system, in an embodiment, informs BIM objects with keynote terminology to identify specified materials and products that should be identified in the model. The integration enables superior coordination between the model and specifications and enables continuous estimating in support of target value delivery.

### Owner Benefits

Owner Requirements Baked In: The owner can build-in project requirements, including their own design and construction standards from the beginning. This proactive approach provides the basis for judging the effectiveness of the design solution in meeting all project requirements.

Transparent Process, Owner Focus: The specification process is no longer hidden from the owner. Active participation is promoted so decisions can be governed by owner requirements and influenced by owner preferences rather than controlled entirely by the design team.

Informed Consent: The process allows for informed consent and provides the opportunity for the owner to formally evaluate and adjust the OPR with respect to the design solution when unexpected conditions or opportunities are discovered during the design process.

Design Validation: Integrating OPR, UF and MF documents in a single location enables the design solution to be easily validated against the OPR and the budget to minimize redesign and project delays.

Risk Management: Active participation by the entire team will reduce uncertainty and potential hidden risk during bidding and construction, evidenced by reduced numbers of requests for information, construction claims, and change orders. Many constructability, logistical, and coordination concerns will be discovered and resolved before the documents are released for use when all stakeholders are given the opportunity to improve outcomes for themselves through active participation.

### Architect/Engineer Benefits

Clearly Established Brief: As design begins, the architect can rely on the consistently structured OPR documentation establishing the parameters for the design problem the architect should solve. The architect will have the capacity to respond to the owner's criteria by developing system and assembly descriptions following a consistent format serving as a checklist to ensure nothing is forgotten. The format enables the architect to easily record system quality, performance, components and the component attributes that are essential for value analysis estimating and validating the design complies with the OPR.

Flexibility to Explore Solutions: During early design stages a variety of solutions can be explored to determine the most appropriate for the project by performance, design, and cost to ensure compliance with the owner's project budget—resulting in the owner's informed consent, recorded as part of the process. Then the architect can proceed with confidence that the decisions and resulting design will be preserved rather than be subjected to value engineering, as cost and value cutting.

Preservation of Design Intent: Proceeding from an OPR and project cost that result from owner informed consent, the architect can have confidence that the decisions and resulting design will be preserved rather than subjected to value engineering.

Design Consultant Management: The architect will be able to manage the specification production progress and coordination for all design consultants. The development process will be transparent and collaborative. Consultants will not be able to hide insufficient progress toward meeting scheduled milestone deliverables. Required specification coordination will be real time. As architects are describing the building cladding, the structural engineer can coordinate the superstructure supporting the cladding and the plumbing engineer can coordinate the roof drains penetrating the cladding.

Coordination of Drawings and Specifications: Designers can request specification modifications as the drawings are developed to ensure proper coordination.

### Specifier Benefits

Effective Communication Across the Project Team: The web-based platform allows the specifiers to communicate with the entire project team, asking questions directly to those most able to accurately respond. Contractual issues to the owner, aesthetic issues to the architect, and engineering issues to the appropriate engineer. The discussions are tracked with the relevant specification text so the team can monitor the development and the specification revisions as the design progresses. Moreover, the designers can request specification modifications as the drawings are developed to ensure proper coordination.

Task Automation: The described system, in an embodiment, will enable specifiers to automate selected tasks, especially the tedious routine tasks that are often prone to human error. The automation will improve overall document quality and coordination among the hundreds of documents required to describe the project. The custom tags will allow specifiers to use a single set of documents for multiple purposes and to choose the specific purpose with the flick of either a global project or local document switch.

Document Repurposing: Custom tags allow specifiers to use a single set of documents for multiple purposes, and to apply a specific purpose to an entire project or a single document.

BIM Coordination: The BIM objects (Revit families) can be linked by a single data entry to the UF systems and assemblies in the described system, in an embodiment. Simply ensure the Revit assembly code matches the UF element number. This will allow for easy comparison to ensure all modeled objects are described in UF and all UF elements are included in the BIM.

### Estimator Benefits

Quicker, More Accurate Estimates: Consistently and well organized data allows estimators to perform cost analyses quickly, especially when the data is organized in the same fashion as estimating software. UF serves as the underlying format for the project documentation and the project estimates, especially during the early design stages. Using the same organization scheme promotes coordination between the project description and estimate allowing for easy confirmation the estimate accurately reflects the scope of the project description.

Assembly Comparison: When the UF documentation describes and entire assembly and the UF based estimate prices that entire assembly, making comparisons of various assemblies to perform the same function is vastly simplified. Plus the UF description allows the added dimension of comparing the system performance in addition to cost, permitting a more informed decision when choosing one system over another as the path the design should take.

Powerful Cost Analysis: System descriptions permit historic comparison more easily. The cost of the building enclosure for the particular building type is expected to be within a particular range of the overall building cost. When the range is exceeded, an analysis is triggered to ensure both the design and the cost are accurately reflecting the design and to determine what influence may be causing the abnormality. On-going cost analysis can have a positive project impact in both cost and schedule by informing design decisions resulting from market trends and labor availability.

### Construction Manager Benefits

Resources and Scheduling to Aligned Building Elements: One of the most difficult project tasks is managing logistics and monitoring schedule production to complete the building construction. Construction crews are assembled to produce work results—the systems and assemblies constituting the ultimate building. Schedules are arranged in manageable chunks so production can be easily monitored and corrected if need be. UF systems lend themselves as the basis for crew assignments. Each UF system can be subdivided by floor, quadrant, and any number of other factors, to create a production scope within the optimal management timeframe, helping manage production rate and providing feedback for process improvements to be made.

Active Participation in Specification Development: The construction team knows the perils of the construction site and can offer insight into specification choices that may have significant schedule, sequence, or coordination consequences. The described system, in an embodiment, allows contractors, their subcontractors, and material suppliers to participate in the specification development. They can lend their experience to avoid predictable pitfalls before they are discovered during construction.

Smoother Construction Process, Reduced Risk: When the construction team participates ambiguity can be eliminated. The need for requests for information (RFI) and change orders and the resulting schedule disruptions will be vastly reduced. Leveraging the construction team participation will expose the inherent, often hidden, risk and construction contingencies associated with today's project delivery models and allow those risks to be removed or properly managed to minimize the impact. When given the right opportunity every business and every individual will gladly give time and lend their expertise to ultimately make their own job easier and consequently improve the eventual outcome for the owner.

Rethinking Specifications, Refocusing Priorities: The industry is changing. Today's design-build, delegated design, and design assist delivery methods require cooperation between the design team and the construction team. And commissioning requires cooperation with the owner to establish OPR and validate design conformance. But legacy systems and processes don't encourage or support cooperative, integrated information development. Specifications are required as a contract document. Accurate specifications are critical to construct the project. That hasn't changed, but specifications can change to unlock their true potential. Integrated specifications embodying all the project requirements—OPR, performance criteria, and design criteria—can enable continuous design validation and serve the life of the project from day one through commissioning and building operations.

In a further embodiment, the construction design generation tool provides version control, wherein users can define versions of each document. Moreover, the tool may further track document events for user-initiated reversion or review. For example, a user may wish to compare the current version to a past version.

The tracked document events may include, for example, events executed via a document menu. These may be such events as version creation, adding a document, creating a new document, importing a document, addressing comments in the document, and addressing edits in the document.

It will be appreciated that various systems and processes have been disclosed herein. However, in view of the many possible embodiments to which the principles of the present disclosure may be applied, it should be recognized that the embodiments described herein with respect to the drawing figures are meant to be illustrative only and should not be taken as limiting the scope of the claims. Therefore, the techniques as described herein contemplate all such embodiments as may come within the scope of the following claims and equivalents thereof.

We claim:

1. A construction design generation tool comprising:
a local non-transitory memory medium;
a network connection configured to selectively access a network for access to non-local resources on the network; and
a processor configured to generate a construction design document by instantiating a construction design template based on data retrieved from the local non-transitory memory medium, receiving user input to populate the construction design template after verifying user permission to access and populate the construction design template, verifying user entries via compliance data retrieved via the network connection from the non-local resources and completing the construction design based on the template, user entry, and compliance data, wherein the construction design includes data arranged in accordance with a plurality of construction specification formats.

2. The construction design generation tool in accordance with claim 1, wherein the processor is further configured to export the construction design document in one of a DOCX and PDF format.

3. The construction design generation tool in accordance with claim 1, wherein verifying user permission to access and populate the construction design template includes accessing a user permission white list.

4. The construction design generation tool in accordance with claim 1, wherein verifying user permission to access and populate the construction design template includes accessing a user permission black list.

5. The construction design generation tool in accordance with claim 1, wherein the construction design is a construction specification.

6. The construction design generation tool in accordance with claim 1, wherein the plurality of construction specification formats include two or more of MasterFormat®, UniFormat®, and UNIFORMAT II.

7. The construction design generation tool in accordance with claim 1, wherein the tool further provides version control wherein users can define versions of each document.

8. The construction design generation tool in accordance with claim 7, wherein the tool further tracks document events for user-initiated reversion or review.

9. The construction design generation tool in accordance with claim 8, wherein the tracked document events comprise events executed via a document menu.

10. The construction design generation tool in accordance with claim 9, wherein the tracked document events include version creation, adding a document, creating a new document, importing a document, addressing comments in the document and addressing edits in the document.
